(19) United States
(12) Patent Application Publication
(10) Pub. No.: US 2008/0227295 A1
(43) Pub. Date: Sep. 18, 2008

(54) Self-aligned contact frequency doubling technology for memory and logic device applications

(76) Inventor: Yijian Chen, Albany, CA (US)

Correspondence Address: Yijian Chen, 1049 Talbot Ave., Albany, CA, 94706, US

(21) Appl. No.: 11/724,695

(22) Filed: Mar. 16, 2007

(51) Int. Cl. H01L 21/461; H01L 21/336

(52) U.S. Cl. 438/691; 257/E21.409; 257/E21.483

(57) ABSTRACT

Contact spatial-frequency doubling technology is invented to pattern a contact-hole array and a row/column (or multiple isolated rows/columns) of contact holes with their density increased to twice of the maximum density achievable during one exposure with a conventional lithographic technology. These contact frequency doubling processes can be used not only in contact-hole patterning for both memory and logic devices, but also applicable for doubling the density of epi-Si (or epi-SiGe, epi-Ge) columns. If introduced to fabricate vertical MOSFET devices wherein the epi-columns act as the transistor body/channel and drain/source is designed in the vertical way, the epi-column doubling technology can enable cost-effective fabrication processes for high-density 4F² DRAM and vertical CMOS applications.

### 1. BACKGROUND OF THE INVENTION

Optical DUV (deep ultraviolet, 193 nm) immersion lithography can be applied to print features down to half-pitch 40 nm [1] and the most promising next-generation technology is EUV lithography scheduled to be introduced for high-volume semiconductor manufacturing at sub-22 half pitch [2]. However, high cost of ownership, mask defects, and limited light source are serious challenges to successful development of cost-effective EUV lithography for future semiconductor industry. As a possible bridge technology between optical DUV immersion (water) and EUV lithography, double patterning has attracted much industrial interest recently [3]. Double patterning technique prints and etches semi-dense patterns twice, and the spatial frequency of the final pattern in the hard mask or resist layer doubles (or the pitch is reduced by half). Technical hurdles of double patterning are the required extremely high overlay accuracy and significant increase of lithographic cost. For example, dense contact holes in DRAM memory, if misaligned in a double patterning process and too close to each other, will suffer from the overlay errors in a deep plasma etching. Spacer lithography, a self-aligned frequency doubling technique for patterning 1-D dense lines/spaces [3], does not work for 2-D patterns such as contact holes. Therefore, a self-aligned contact frequency doubling technology with no need of exposing wafer twice, can avoid the challenging overlay control issues, improve the process yield, and reduce the lithographic cost.

Several contact spatial-frequency doubling techniques are invented to pattern features with their density increased to twice of the maximum density achievable during one exposure with a conventional lithographic technology. These contact frequency doubling processes can be used not only for contact-hole patterning in both memory and logic devices, but also applicable for doubling the density of epi-Si (or epi-SiGe, epi-Ge) columns when combined with a selective epi growth process. If introduced to fabricate vertical MOSFET devices, above epi-Si (or SiGe, Ge) column doubling process can enable practical device fabrication processes for high-density 4F² DRAM (conventionally, 2F×2F is the area occupied by a DRAM cell, and F is the minimum feature size resolvable with a lithographic process) and vertical CMOS applications.

### 2. DETAILED DESCRIPTION OF THE INVENTION

In FIG. 1, we show the top view (a) and 3-D cross-section view (b) of semi-dense contact holes cut through the position as indicated by the arrows. They are the original (first) batch of contact holes patterned with standard lithographic and etching processes. The contacts' minimum center-to-center distance as shown in the figure (P=2F) is the minimum pitch resolvable with a lithographic tool. In other words, the minimum half pitch of this semi-dense pattern corresponds to the minimum feature size F resolvable with a conventional lithographic tool. Our goal is adding another batch of contact holes to double the contact-hole density with the final pitch P_{new}=\sqrt{2}F as shown in (c) and (d). This pitch size shrinks by a factor of \sqrt{2} from the original pitch size (P=2F, printed with a lithographic tool). It is evident from FIG. 1 that both contact spatial-frequency in every row and the total contact number double. It should be kept in mind that we demonstrate the concept with ideal square contacts in FIG. 1. However, such perfect square contacts will be difficult to print as the contact corners tend to be rounding. Consequently, there is a minor difference between the shapes of the original batch of contact holes (patterned with a lithographic tool) and the second batch of contact holes added through other processes to be demonstrated later.

The process to achieve contact frequency doubling is shown FIG. 2. We start from a stack of multiple layers on the wafer in step (1), and first print the contact-hole pattern on the resist layer (not shown) with a lithographic process, whose top view is depicted in FIG. 1(a). The formed pattern on the resist is then transfer into the underneath stack layers with an anisotropic plasma etching. After the resist is stripped off, the etched structure is shown in step (2) of FIG. 2. The top protective (e.g., a hard-mask layer), sacrificial (orange), targeted (blue), and substrate (gray) layers will then be exposed to a chemical solution which will partially etch the sacrificial layer in step (3). It is important that we choose a sacrificial material that can be wet etched with certain highly selective etching solution which will not attack the top hard-mask layer, targeted and substrate layers. Moreover, the chosen chemical solution should allow us to control the wet etch rate accurately such that the remaining (horizontal) width of the sacrificial material will exactly reduce the pitch size by half (to be described later). In general, the remaining width can be controlled by adjusting the etch time in above wet process. The top protective layer as shown in FIG. 2 (3) must be stripped off if it snaps down due to the stiction force of fluid after the sacrificial etching. Otherwise, a deposition of the hard-mask material as shown in step (4) will follow directly. This material will be used as a self-aligned hard mask when we etch the added contact holes into the targeted layer as shown in step (7). It should be kept in mind that the hard-mask material must be resistive to the dry etching of the targeted layer, but not necessary to be the same material as the top protective layer (we do not distinguish them in the figure though). After the deposition process filling the trenches, there might be some small cavities formed in the trenches, but they are not harmful to the whole process. Then a CMP (chemical-mechanical polishing) or etch process will be applied to remove the top protective layer and expose the sacrificial layer. The sacrificial material will be released with a wet etch process or be etched away with a highly selective dry etch process. Finally an anisotropic dry etch into the targeted layer and post-etch wet release of the hard-mask material will double the contact density as shown in the cross-section view of FIG. 2 (8) or the top view of FIG. 1 (c).

This contact-hole frequency doubling technology can also be used to growepi-Si (or epi-SiGe, epi-Ge) columns for high-density 4F² DRAM device wherein the epi-columns are used as the body/channel and source/drain is designed in the vertical way. We start from the structure shown in FIG. 2(8) with the crystalline Si (or SiGe, Ge) as the substrate material. The exposed crystalline Si (or SiGe, Ge) area will act as the seed for epi growth. Using a standard epi process, we can grow epi-Si (or SiGe, Ge) columns in the opened areas with the column density as twice as available without using frequency doubling technology.

The process flow demonstrated in FIG. 2 can also be applied to pattern a single row/column of dense contacts (as shown in FIG. 3), and multiple rows/columns of dense contacts wherein every row/column is far enough from each other (as shown in FIG. 4). However, due to the exposure of the edge areas of the sacrificial material to the etching solution, the contact-to-edge spacing requires special attention. For example, the contact-to-edge spacing in y direction (top and bottom) should be both equal to F/2 as shown in FIG. 3 to ensure that the added (second) batch of contact holes have the same size in x and y directions, and are self-aligned to the original batch of contact holes (printed with a lithographic tool). To demonstrate this design rule, we show the shrinking process of the sacrificial layer during a wet etching process in FIG. 5. It is helpful to keep in mind that both the contact holes and the surrounding areas are filled with chemical solution which etches the sacrificial material in an isotropic manner. If we want to further transfer the structure formed in the targeted layer (shown in FIG. 2(8)) into the substrate, an extra anisotropic plasma etching is needed. However, as we can see from FIG. 3(a), the extension of the active area is limited by the specification of contact-to-edge spacing. As a result, the surrounding areas beyond the coverage of the active area will be attacked by the plasma during a dry etching process. Therefore, a protective layer with only active area opened must be used to avoid the undesired etching of surrounding areas. This can be achieved using a resist layer patterned with a lithographic process which does not require high resolution and overlay capabilities. Density doubling of these types of contact patterns can be useful for logic device applications.

### 3. BRIEF DESCRIPTION OF THE FIGURES

FIG. 1. depicts the top view (a) and 3-D cross-section view (b) of semi-dense contact holes cut through the position as indicated by the arrows; and (c) and (d) corresponding to the dense contact holes fabricated using the self-aligned frequency (density) doubling technology.

FIG. 2. depicts the process flow to double the spatial frequency/density of contact holes.

FIG. 3. depicts the top view (a) and 3-D cross-section view (b) of a row of semi-dense contact holes; and (c) and (d) corresponding to a row of dense contact holes fabricated using the self-aligned frequency doubling technology.

FIG. 4 depicts the top view of an example of multiple rows/columns of dense contact holes fabricated using the self-aligned frequency (density) doubling technology. The minimum space between two active areas is F/2 as indicated.

FIG. 5. The shrinking process of the sacrificial layer during a wet etching process to double the density of a row of contact holes.

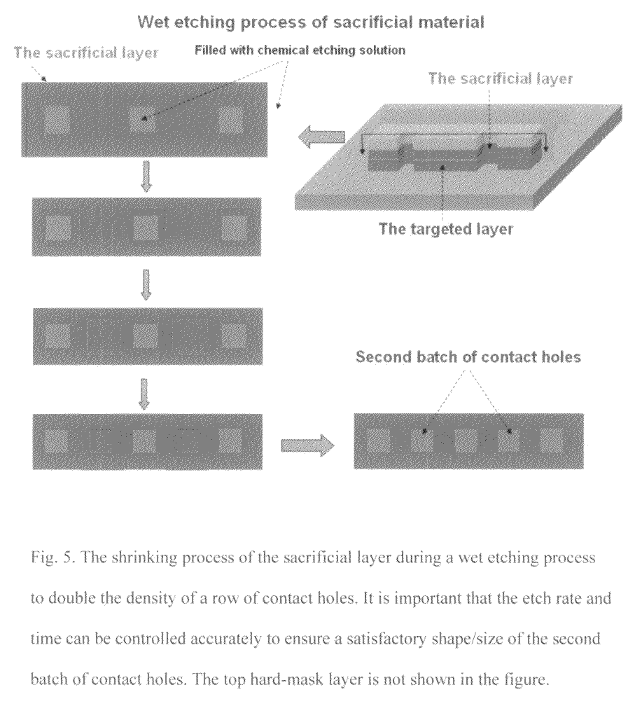

### 4. CONCLUSION

A novel spatial-frequency doubling technology has been developed to double the density of contact-hole patterns. These contact frequency doubling processes can be applied not only in contact-hole patterning for both memory and logic devices, but also for doubling the density of epi-Si (or epi-SiGe, epi-Ge) columns which can act as the transistor body/channel. Design rules of mask patterns are presented.

### REFERENCES

[1] G. A. Gomba, “Collaborative innovation: IBM's immersion lithography strategy for 65 nm and 45 nm half-pitch nodes & beyond,” (plenary talk), SPIE Advanced Lithography, San Jose, Calif., 2007.
[2] International Technology Roadmap for Semiconductors (ITRS), 2006 version
[3] W. H. Arnold, “Metrology challenges of double exposure/double patterning,” (invited talk), SPIE Advanced Lithography, San Jose, Calif., 2007.

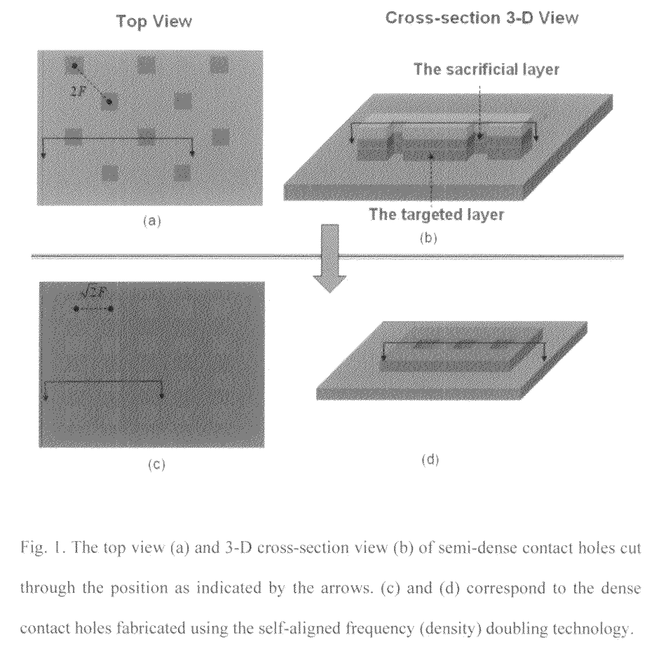

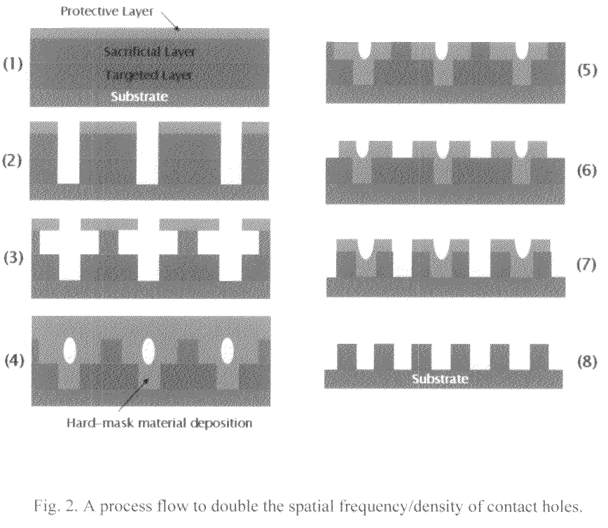

1. A process to double the spatial frequency (density) of contact-hole array by adding one batch of self-aligned contact holes to the original batch of contact holes which are patterned with lithographic and etching process, the sequence comprising:
a. starting from a stack of multiple layers on the wafer as shown in FIG. 2(1), printing the original batch of contact holes on the resist layer (not shown in the figures) with a lithographic process, and transferring the formed pattern on the resist into the underneath stack layers with an anisotropic plasma etching.
b. stripping off the resist with the etched structure shown in the step (2) of FIG. 2, exposing the top protective (e.g., a hard-mask layer), sacrificial (orange), targeted (blue), and substrate (gray) layers to a chemical solution which will partially etch the sacrificial layer in step (3). (It is important that we choose a sacrificial material that can be wet etched with certain highly selective etching solution which will not attack the top hard-mask layer, targeted and substrate layers. Moreover, the chosen chemical solution should allow us to control the wet etch rate accurately such that the remaining (horizontal) width of the sacrificial material will exactly reduce the pitch size by half.)
c. an optional step to strip off the top protective layer as shown in FIG. 2 (3) if it snaps down due to the stiction force of fluid after the sacrificial etching.
d. a following deposition of the hard-mask material as shown in step (4) which will be used as a self-aligned hard mask when we etch the added contact holes into the targeted layer as shown in step (7). (The hard-mask material must be resistive to the dry etching of the targeted layer, but not necessary to be the same material as the top protective layer even we do not distinguish them in the figure though.)
e. a CMP (chemical-mechanical polishing) or etching process applied to remove the top protective layer and expose the sacrificial layer as shown in step (5).
f. releasing the sacrificial material with a wet etch process or etching the sacrificial material with a highly selective dry etch process as shown in step (6).
g. a final anisotropic dry etching into the targeted layer as shown in step (7), and post-etch wet release of the hard-mask material, doubling the contact density as shown in the cross-section view of FIG. 2 (8) or the top view of FIG. 1 (c).

2. The method of claim 1, further adapted to grow epi-Si columns which can be used as the body/channel of MOSFET devices with source/drain designed in the vertical way, the sequence further comprising:
a. starting from the structure shown in FIG. 2(8) with the crystalline Si as the substrate material, wherein the exposed crystalline Si in the holes will act as the seed for epi-Si growth.
b. using a standard epi-Si process to grow epi-Si columns in the opened hole areas.

3. The method of claim 2, but the substrate material is replaced by epi-SiGe or epi-Ge.

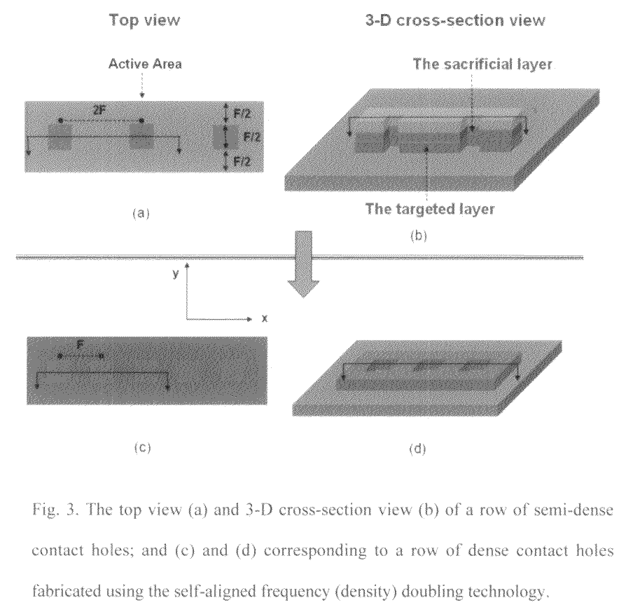

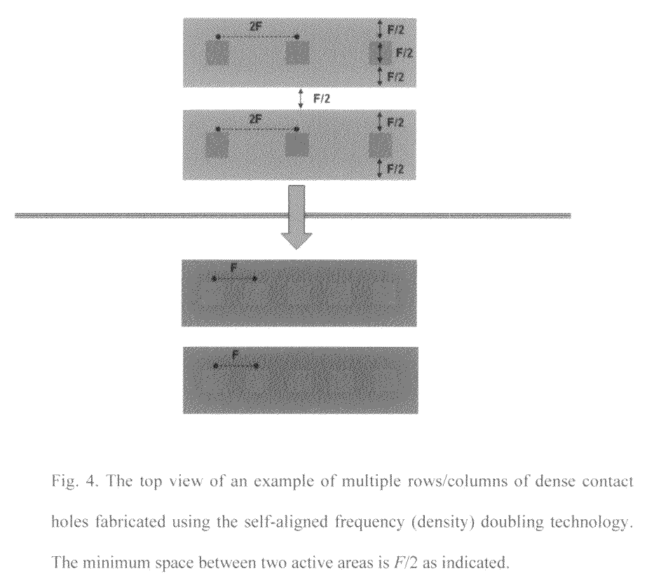

4. The method of claim 1, adapted to print a single row/column of dense contacts (as shown in FIG. 3) and multiple rows/columns of dense contacts wherein every row/column is far enough from each other (as shown in FIG. 4), the sequence comprising:
a. setting up design rules for patterning a row of dense contact holes, wherein the contact-to-edge spacing in y direction (top and bottom) should be both equal to F/2 (F: the minimum half pitch a lithographic tool can resolve) as shown in FIG. 3(a) to ensure that the added (second) batch of contact holes have the same size in x and y directions, and are self-aligned to the original batch of contact holes printed with a lithographic tool.
b. an anisotropic plasma etching to further transfer the contact holes formed in the targeted layer (shown in FIG. 2(8)) into the substrate.
c. a protective resist or hard-mask layer with the active area opened to avoid the undesired etching of the surrounding areas in above plasma etching, for which a lithographic process is required, but with no need of high resolution and overlay capabilities. (Due to overlay errors, some boundary overlap between this opened area and the active area underneath may be required to guarantee a full coverage and protection of the surrounding areas.)
